(19) United States
(12) Patent Application Publication
(10) Pub. No.: US 2025/0072181 A1
(43) Pub. Date: Feb. 27, 2025

(54) LIGHT EMITTING DEVICE

(71) Applicant: KABUSHIKI KAISHA TOKAI RIKA DENKI SEISAKUSHO, Aichi (JP)

(72) Inventor: Kunitaka Takahashi, Aichi (JP)

(73) Assignee: KABUSHIKI KAISHA TOKAI RIKA DENKI SEISAKUSHO, Aichi (JP)

(21) Appl. No.: 18/801,628

(22) Filed: Aug. 12, 2024

(30) Foreign Application Priority Data
Aug. 22, 2023 (JP) 2023-134851

(51) Int. Cl. H01L 33/60; H01L 25/075; H01L 33/50

(52) U.S. Cl. CPC H01L 33/60; H01L 25/0753; H01L 33/50

(57) ABSTRACT

A light emitting device includes a light emitting diode (LED) element, a wall unit, and at least one or more reflective units. The LED element is provided on a substrate, the wall unit is provided on the substrate around the LED element, and the at least one or more reflective units have a tapered shape that narrows towards a side opposite to the substrate, and are provided between the LED element and the wall unit.

### CROSS-REFERENCE TO RELATED APPLICATION

This application claims the priority benefits of Japanese application no. 2023-134851, filed on Aug. 22, 2023. The entirety of the above-mentioned patent application is hereby incorporated by reference herein and made a part of this specification.

### BACKGROUND

### Technical Field

The disclosure relates to a light emitting device.

### Description of Related Art

In recent years, micro light emitting diode (LED) displays have been attracting attention as a new display technology. A micro LED display is a display device in which miniaturized LED elements are used as pixels and arranged in an array on the display surface. A micro LED display can display images with high contrast and high response speed by individually controlling the light emission of LED elements in each of pixels.

For example, Patent Document 1 (Japanese Patent Application Laid-Open Publication No. 2020-205417) discloses a micro LED display device in which LED elements arranged on a display substrate are separated from each other by light-shielding partition walls.

However, when an LED element is formed by stacking a p-type semiconductor and an n-type semiconductor in the height direction, light emitted from the LED element is primarily emitted from the side surfaces of the LED element. In the micro LED display device disclosed in the above-mentioned Patent Document 1, light-shielding partition walls are provided in the side direction of the LED elements, making it difficult to effectively utilize the light emitted in the side direction of the LED elements.

Therefore, the disclosure is to provide a new and improved light emitting device that may enhance light emission efficiency by more effectively utilizing light emitted from LED elements.

### SUMMARY

According to an aspect of the disclosure, a light emitting device which includes an LED element, a wall unit, and at least one or more reflective units is provided. The LED element is provided on a substrate, the wall unit is provided on the substrate around the LED element, and the at least one or more reflective units have a tapered shape that narrows towards a side opposite to the substrate, and are provided between the LED element and the wall unit.

### BRIEF DESCRIPTION OF THE DRAWINGS

FIG. 1 is a schematic cross-sectional view showing the cross-sectional structure of a light emitting device according to an embodiment of the disclosure.

FIG. 2 is a schematic cross-sectional view showing a first planar structure of the light emitting device according to the same embodiment.

FIG. 3 is a schematic cross-sectional view showing a second planar structure of the light emitting device according to the same embodiment.

### DESCRIPTION OF THE EMBODIMENTS

As described above, according to the disclosure, the light emission efficiency of the light emitting device may be enhanced by more effectively utilizing light emitted from the LED element.

An exemplary embodiment of the disclosure will be described in detail below with reference to the accompanying drawings. Further, in the specification and drawings, components having substantially the same functional configuration are assigned the same reference numerals, and duplicate descriptions are omitted.

### <1. Cross-Sectional Structure>

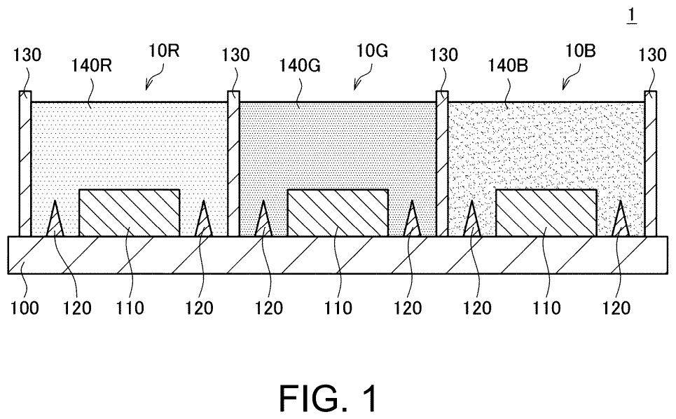

First, with reference to FIG. 1, the cross-sectional structure of a light emitting device according to an embodiment of the disclosure will be described. FIG. 1 is a schematic cross-sectional view showing the cross-sectional structure of a light emitting device 1 according to the embodiment. It should be noted that FIG. 1 shows the structure of a cross-section of the light emitting device 1 cut in a direction perpendicular to a display surface.

As shown in FIG. 1, the light emitting device 1 includes a substrate 100, an LED element 110, a reflective unit 120, a wall unit 130, and phosphors 140R, 140G, and 140B. For example, the light emitting device 1 is a full-color display device based on the RGB color model using a red pixel 10R, a green pixel 10G, and a blue pixel 10B.

It should be noted that the red pixel 10R, the green pixel 10G, and the blue pixel 10B may also be collectively referred to as pixels 10 when not being distinguished from one another. Similarly, the phosphors 140R, 140G, and 140B may also be collectively referred to as phosphors 140 when not being distinguished from one another.

The substrate 100 serves as a support for the pixels 10, and the pixels 10 are provided in an array on a main surface of the substrate 100. Although not shown in the figure, the substrate 100 is also provided with a driving circuit for individually driving each of the pixels 10, and a control circuit for controlling the driving of each of the pixels 10. The substrate 100 may be, for example, a glass substrate, a glass epoxy substrate, an epoxy substrate, a polyimide substrate, or a (meth)acrylic substrate, or the substrate 100 may be a flexible substrate made of polyester or polyethersulfone.

The LED element 110 is provided for each of the pixels 10 arranged in an array on the main surface of the substrate 100. For example, the LED element 110 may be provided for each of the pixels 10 arranged in a matrix pattern.

The LED element 110 is composed of a pn junction formed by joining a p-type semiconductor and an n-type semiconductor, and emits light when a forward voltage is applied. Specifically, when a forward voltage is applied to electrodes of the LED element 110, electrons and holes are injected into the LED element 110 from the electrodes. As a result, the LED element 110 can emit energy approximately equivalent to a band gap as light upon recombination when the injected electrons and holes recombine across a forbidden band near a pn junction unit.

The LED element 110 may, for example, emit ultraviolet light with a wavelength of around 300 nm. The ultraviolet light emitted from the LED element 110 is converted into red light, green light, or blue light by the phosphors 140R, 140G, and 140B.

The LED element 110 may be composed of a pn junction of compound semiconductors such as InGaN, GaN, or AlGaN. Additionally, the LED element 110 may form a pn junction by stacking compound semiconductors in a direction perpendicular to the main surface of the substrate 100.

The wall unit 130 is provided on the main surface of the substrate 100 between the pixels 10, and extends in a wall-like manner in a direction perpendicular to the main surface of the substrate 100. The wall unit 130 can separate the pixels 10 from each other by being provided in a grid pattern between the pixels 10. The wall unit 130 may be composed of an organic resin such as epoxy resin, (meth)acrylic resin, polyurethane, polyester, polyimide, polyolefin, or polysiloxane. Additionally, the wall unit 130 may contain a black pigment to impart light-shielding properties.

Furthermore, the wall unit 130 is provided to extend to a height higher than a height of the LED element 110. This allows the pixel 10 to be filled with the phosphor 140 between the wall units 130 so as to cover the LED element 110, thereby enabling efficient conversion of the ultraviolet light emitted from the LED element 110 into red light, green light, or blue light by the phosphor 140.

The reflective unit 120 has a tapered shape that narrows towards a side opposite to the substrate 100 and is provided on the main surface of the substrate 100 between the LED element 110 and the wall unit 130. The reflective unit 120 can reflect light emitted in the side direction of the LED element 110 towards the side opposite to the substrate 100 by having a surface composed of metal, or by being composed of materials with different refractive indices between the surface and an interior. As a result, the reflective unit 120 can allow more light emitted from the LED element 110 to enter the phosphor 140 without being absorbed by the substrate 100 and the wall unit 130, thereby further enhancing the light emission efficiency of the pixel 10.

For example, the reflective unit 120 may be a tapered structure composed of metallic materials such as silver, copper, or aluminum. Alternatively, the reflective unit 120 may be a tapered structure of organic resin coated on the surface thereof with metallic materials such as silver, copper, or aluminum. Furthermore, the reflective unit 120 may be a structure formed by layering organic resin with different refractive indices between the interior and the surface.

In FIG. 1, the reflective units 120 are respectively provided on both sides of the LED element 110 in a manner of sandwiching the LED element 110, but it is sufficient for at least one or more reflective units 120 to be provided between the LED element 110 and the wall unit 130. However, preferably, the reflective unit 120 may be provided so as to planarly surround the LED element 110 on the main surface of the substrate 100, as will be described later. In this case, the reflective unit 120 may be provided to continuously surround the LED element 110, or the reflective unit 120 may be provided to discretely surround the LED element 110.

A height of the reflective unit 120 may be approximately the same as the height of the LED element 110. However, it is preferable that the height of the reflective unit 120 is lower than the height of the LED element 110. This is because when being provided at approximately the same height as the LED element 110, the reflective unit 120 can reflect most of the light emitted from the side direction of the LED element 110. In other words, making the height of the reflective unit 120 even higher than the height of the LED element 110 is not preferable as such a way offers little benefit in terms of cost. Specifically, even if the height of the reflective unit 120 is made higher than the height of the LED element 110, such a way is not desirable because the increase in light emission efficiency of the pixel 10 is small compared to the increase in manufacturing cost, and the amount of phosphor 140 that can be filled between the wall units 130 decreases as the reflective unit 120 becomes larger.

It should be noted that the reflective unit 120 does not need to be provided in a tapered shape as long as the reflective unit 120 can reflect light emitted from the side direction of the LED element 110 towards the side opposite to the substrate 100. In other words, it is sufficient for the reflective unit 120 to have a side surface facing the LED element 110 inclined so that the side surface moves away from the LED element 110 towards the side opposite to the substrate 100. In such a case, a side surface of the reflective unit 120 not facing the LED element 110 may be inclined in any direction, or the side surface may not be inclined at all and be perpendicular to the main surface of the substrate 100.

The phosphor 140 is filled between the wall units 130 so as to cover the LED element 110 and the reflective unit 120, and converts the light emitted from the LED element 110 into red light, green light, or blue light. For example, the phosphor 140R is a fluorescent substance that emits red fluorescence by absorbing ultraviolet light, the phosphor 140G is a fluorescent substance that emits green fluorescence by absorbing ultraviolet light, and the phosphor 140B is a fluorescent substance that emits blue fluorescence by absorbing ultraviolet light. The phosphor 140 may be a known inorganic or organic fluorescent substance. Additionally, the phosphor 140 may be a phosphorescent substance, or the phosphor 140 may be a quantum dot of which a wavelength of light emitted can be controlled by size.

It should be noted that upper parts of the phosphor 140 and the wall unit 130 are sealed by a transparent film or transparent substrate (not shown). The red light, green light, and blue light emitted from each of the pixels 10 pass through the transparent film or transparent substrate and are released to the outside.

With the above configuration, the light emitting device 1 according to the embodiment can allow more light emitted from the LED element 110 to enter the phosphor 140, thereby further improving the light emission efficiency of the pixel 10. Consequently, the light emitting device 1 can effectively utilize the space between the LED element 110 and the wall unit 130 by means of the reflective unit 120, while further improving the light emission efficiency of the pixel 10.

In the light emitting device 1, the wall unit 130 that separates the pixels 10 and the reflective unit 120 that reflects light emitted from the LED element 110 are constructed separately. Therefore, in the light emitting device 1 the pixels 10 can be separated with a more spatially efficient and simpler wall unit 130, allowing for an increase in the amount of phosphor 140 filled between the wall units 130. Furthermore, the light emitting device 1 can efficiently reflect light emitted from the LED element 110 to the phosphor 140 using a smaller reflective unit 120.

### <2. Planar Configuration>

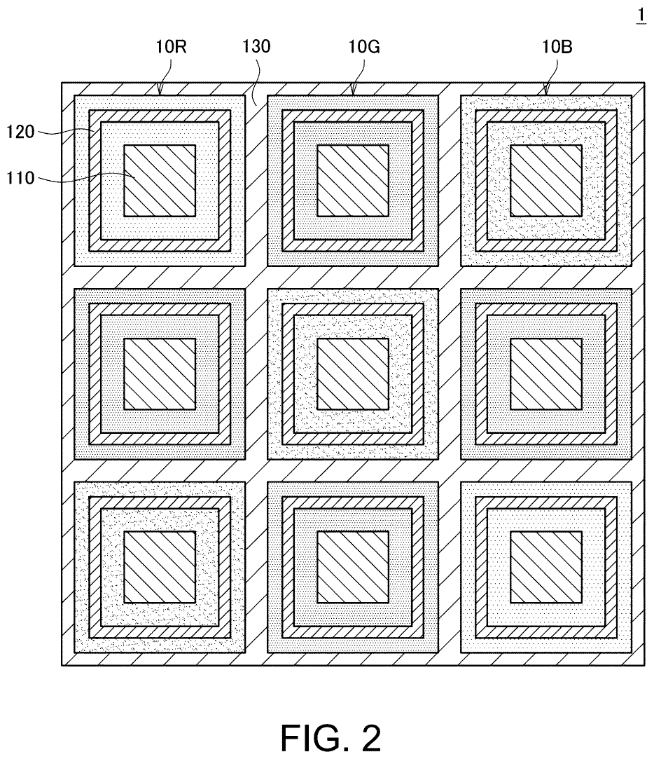

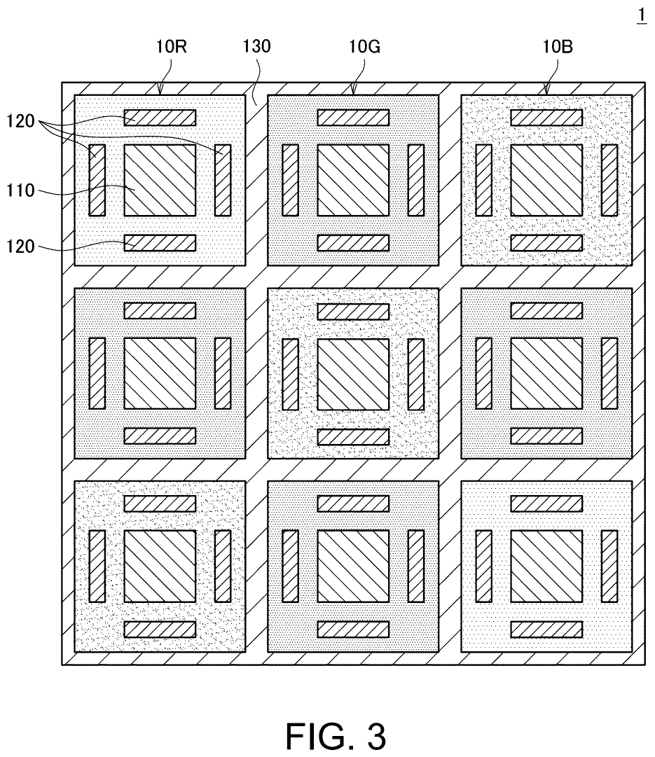

Next, referring to FIGS. 2 and 3, planar configurations of the light emitting device 1 according to the embodiment will be described. FIG. 2 is a schematic plan view showing a first planar configuration of the light emitting device 1 according to the embodiment. FIG. 3 is a schematic plan view showing a second planar configuration of the light emitting device 1 according to the embodiment.

As shown in FIGS. 2 and 3, in the light emitting device 1, the pixels 10 are arranged in a matrix pattern in a so-called Bayer arrangement. Between the pixels 10, the wall units 130 extend in a grid-like manner in vertical and lateral directions perpendicular to each other. Within each of the pixels 10, an LED element 110 having a rectangular planar shape is provided.

### (First Planar Configuration)

As shown in FIG. 2, in the first planar configuration, the reflective unit 120 is provided to surround the outer periphery of the LED element 110. Specifically, the reflective unit 120 may be provided to continuously surround the outer periphery of the rectangular planar-shaped LED element 110 in a frame-like manner. By surrounding the entire periphery of the LED element 110 for one complete revolution, the reflective unit 120 can reflect more light emitted from the side direction of the LED element 110 towards the side opposite to the substrate 100 (that is, towards the front direction of the paper surface in FIG. 2).

### (Second Planar Configuration)

As shown in FIG. 3, in the second planar configuration, the reflective unit 120 extends to face each of sides of the LED element 110, and is provided separately from each other. Specifically, the reflective unit 120 may be provided in a linear shape at four positions facing each of the sides of the rectangular planar-shaped LED element 110. By providing the reflective unit 120 separately around the periphery of the LED element 110, the reflective unit 120 can be formed through a simplified manufacturing process. Even in such a case, the reflective unit 120 can sufficiently reflect light emitted from the side direction of the LED element 110 towards the side opposite to the substrate 100 (that is, towards the front direction of the paper surface in FIG. 3). Furthermore, by being separated from each other, the reflective unit 120 allows for more uniform filling of the phosphor between the LED element 110 and the wall unit 130. Therefore, according to the second planar configuration, the reflective unit 120 can improve the light emission efficiency of the phosphor 140.

While the exemplary embodiment of the disclosure have been described in detail with reference to the attached drawings, the disclosure is not limited to such an example. It is apparent that those skilled in the art to which the disclosure pertains can devise various changes or modifications within the scope of the technical idea described in the claims. It is understood that these changes or modifications naturally fall within the technical scope of the disclosure.

While the light emitting device 1 according to the above embodiment has been described as a full-color display device based on the RGB color model, the disclosure is not limited to such an example. The light emitting device 1 according to the embodiment may be a light emitting device such as a lamp, light source, or lighting device that does not have the LED elements 110 arranged as the pixels 10, but instead includes a single LED element 110, a wall unit 130, and a reflective unit 120.

What is claimed is:

1. A light emitting device, comprising:
a light emitting diode (LED) element, provided on a substrate;
a wall unit, provided on the substrate around the LED element; and
at least one or more reflective units, having a tapered shape that narrows towards a side opposite to the substrate, and provided between the LED element and the wall unit.

2. The light emitting device according to claim 1, wherein the reflective units are respectively provided on both sides of the LED element in a manner of sandwiching the LED element.

3. The light emitting device according to claim 2, wherein the reflective unit is provided to surround the entire periphery of the LED element.

4. The light emitting device according to claim 1, wherein a height of the reflective unit is lower than a height of the LED element.

5. The light emitting device according to claim 1, wherein at least a surface of the reflective unit is composed of metal.

6. The light emitting device according to claim 1, wherein a phosphor that emits fluorescence by light emitted from the LED element is filled in a space separated by the wall unit around the LED element.

7. The light emitting device according to claim 1, wherein
a plurality of the LED elements are provided for each of pixels arranged on the substrate, and
the wall unit separates the LED elements from each other for each of the pixels.
